(19) United States
(12) Patent Application Publication
(10) Pub. No.: US 2004/0030976 A1
(43) Pub. Date: Feb. 12, 2004

(54) Partial BIST with recording of the connections between individual blocks

(76) Inventors: Majid Ghameshlu, Wien (AT); Karlheinz Krause, Planegg (DE); Herbert Taucher, Moedling (AT)

Correspondence Address: Kevin R. Spivak, Morrison & Foerster LLP, Suite 300, 1650 Tysons Boulevard, McLean, VA, 22102, US

(21) Appl. No.: 10/419,225

(22) Filed: Apr. 21, 2003

(30) Foreign Application Priority Data
Apr. 22, 2002 (EP) 02008956.1

(51) Int. Cl. G01R 31/28

(52) U.S. Cl. 714/732

(57) ABSTRACT

A component with integrated circuits combined into functional blocks, in which case the functional blocks have connections between them and a relevant residual logic. The residual logic of the functional blocks is first tested by entering test data into the residual logic and a first signature is output for each block, and then the connections between the blocks are tested by transferring test data via the connections and a second signature is output.

### CLAIM FOR PRIORITY

This application claims priority to European Application No. 02008956.1 which was published in the German Language on Apr. 22, 2002.

### TECHNICAL FIELD OF THE INVENTION

The invention relates to a method and a device for testing an electronic component with integrated circuits combined into functional blocks, and in particular, with functional blocks interconnected and having a residual logic.

### BACKGROUND OF THE INVENTION

Electronic components of this type often take the form of Applications-Specific-Integrated-Circuits (ASICs). ASICs designate an arrangement of logical gate and memory circuits on an individual silicon wafer. ASICs are a collection of circuits with simple functions such as flip-flops, inverters, NANDs and NORs, as well as more complex structures such as memory arrangements, adders, counters and phase-locked loops. The various circuits are combined into an ASIC in order to perform a specific application. In this connection ASICs are used in a large number of products, for example consumer products such as video games, digital cameras, in vehicles and PCs, as well as in high-end and technology products such as workstations and supercomputers.

To check that an ASIC is functioning correctly various “Design-for-Test” (DFT methods) are known. The advantage of the DFT method lies in the fact that during the construction of the chip switching elements are inserted that allow later scan-based testing, reduce the number of test points needed on the board of the ASIC and at the same time get around the problem of unavailable access points on the chip.

One of the these methods is the “Built-In-Self-Test” (BIST). The BIST provides BIST input cells via which a test vector is entered into the ASIC logic to test the circuits within the logic along scan paths. The outputs from the logic stimulated by the test vector arrive in BIST output cells which represent a test response evaluator (TAA) for the BIST methods and form the test signature or signature for the logic. The signatures can subsequently be analyzed, for example by comparison with a theoretical, expected signature to indicate any errors that may be present in the logic.

In general, the logic of an ASIC comprises a number of logic blocks, each of which accepts subtasks for the total ASICS. The expanded BIST procedures for ASICs with a number of blocks are basically subdivided into two categories, with both methods using the scan paths built into the ASIC.

(A) Total BIST:

With what is referred to as an overall BIST all blocks of the logic relevant for the BIST are tested with a procedure which extends across the entire logic, and the result is a signature that is available for the entire ASIC. The only exceptions to this rule are the ASIC-internal RAMs and ROMs or other subblocks that are legally protected, and are not available to the BIST. The advantages of this method are as follows: As well as the relevant blocks, the connections between these blocks are also tested. Likewise only one BIST controller has to be implemented for the entire ASIC. A disadvantage of the total BIST method however is that the procedure extends across the entire logic, so that the execution sequence is complicated and cannot be executed in parallel. Furthermore, a test pattern generator (TMG) and a test response evaluator (TAA) must be provided, that include all functional inputs and outputs, as well as the many part scan chains created separately for the BIST. This represents a major effort. Above and beyond this all inputs and outputs of the sub scan chains (consisting of 50 to 100 flip-flops) have wiring to the TMG and TMA implemented around the ASIC.

(B) Partial-BIST

With the partial BIST all blocks are tested in parallel but independently of each other. The resulting signatures of the individual blocks are then combined into a corresponding total signature of the ASIC. Advantageously the execution sequence of the partial BIST can be implemented in parallel, i.e. the test times are reduced and the design is simpler than with the total BIST, thus reducing the effort. With the partial BIST however there are the following disadvantages: Each block is surrounded by its own TMG and TAA. This leads to a large overhead and to changes of the timing relationships of the functional inputs and outputs. Furthermore the connections between the blocks and from/to the ASIC pins are not tested. Over and above this the BIST logic consists of one central and many local controllers with adversely affects the number of BIST elements to be added. The partial BIST is typically described in “Essentials of electronic testing for digital, memory and mixed-signal VLSI circuits”, Michael L. Bushnell et al, Kluwer Academic Publishers, ISBN 0-7923-7991-8.

The requirements relating to the BIST in electronic systems and thereby the requirements for the hardware, in particular for custom electronic ASIC components, have increased sharply in recent years.

### SUMMARY OF THE INVENTION

In the invention, there is a procedure of finding a component and a BIST method in which the highest possible test coverage is achieved, but in which the test is simple to implement and the BIST duration is short. In this case the overhead or the effort for the BIST should not exceed a sensible level.

In one embodiment of the invention, there is a method for testing an electronic component the residual logic of the functional blocks is tested by entering test data into the residual logic and outputting a first signature for each block and subsequent testing of the connections between the blocks by transferring test data over the connections and outputting a second signature.

The two-part testing of the ASIC, i.e. testing of all blocks in parallel (block BIST) and subsequent testing of the connection between the blocks (connection BIST) produces the following advantages: The effort for the “Design-for-Test” is less because of the parallel block BIST (first stage). The Test coverage by the BIST method in accordance with the invention is higher since the connections between the blocks are included (second stage).

In another embodiment the first and second signatures are collected at a test controller and an overall signature is created for the component. In this way a total evaluation of the component despite the two-part test method is possible.

In still another embodiment of the invention, the testing of the residual logic of the relevant blocks is undertaken in parallel. This considerably shortens the test times

In accordance with the one aspect the testing of the connections and of the relevant blocks is undertaken in parallel so that in this stage of the BIST the test times are also to be reduced.

In yet another embodiment each functional block features scan chain input flip-flops and scan chain output flip-flops, in which case for the testing of the residual logic and the testing of the connections the scan chain input flip-flops and scan chain output flip-flops are connected together by a local controller in each case into a shift register. In this way the shift register can be formed for the test pattern generators and the test response generators for the two-part BIST procedure.

In another embodiment, the scan chain input flip-flops and the scan chain output flip-flops are each connected into a linear feedback shift register. This means that no external test vector generator is needed in order to enter test vectors into the test pattern generator.

In still another embodiment, the scan chain input flip-flops and/or scan chain output flip-flops can be coupled with a test vector generator to provide test data for the shift register. In this way, for example, more complex test vectors that cannot be created by an LFSR are inserted. The scan chain input flip-flops and scan chain output flip-flops here can be supplied by a single, central, global test vector generator, or a test vector generator is assigned to each functional block, which optionally, depending the stage of the procedure, can be coupled to either the scan chain input flip-flops or the scan chain output flip-flops.

In yet another embodiment of the invention, the scan chain input flip-flops act as a test pattern generator and the scan chain output flip-flops as a test response evaluator for the parallel testing of the residual logic and for testing the connections the scan chain input flip-flops act as a test response evaluator and the scan chain output flip-flops as a test pattern generator. This avoids the need for additional logic through multiple TMGs and TAAs.

In another embodiment of the invention, there is an electronic component in which each functional block features a first and a second shift register, whereby the first shift register provides test data for testing the residual logic which is then accepted by the second shift register after passing through the residual logic and is provided as a first signature, and whereby for testing the connections the second shift register provides test data for testing the connections which is accepted by the first shift register after it has passed through the output and input logic and is provided as the second signature.

The advantages already mentioned above with regard to the method in accordance with the invention also apply to the component in accordance with the invention. Above and beyond this there are also other advantages:

In one embodiment, each functional block features a local test controller which controls the first and the second shift register. The test controller in this case controls the procedure in both stages by sending the BIST mode signal to the TMG and TAA indicating whether the scan chain input flip-flops and the scan chain output flip-flops of the TMGs and TAAs are accepting data or are pushing data along the shift register.

In another embodiment, a global test controller is connected to the local test controllers of the functional blocks and sends a start signal to these in order to provide central starting of the BIST.

In still another embodiment, reset logic is provided which is connected to the local test controllers of the functional blocks and sends a reset signal to these in order to access the local test controller so that it can reset the functional blocks before the block BIST and before the connection BIST.

In yet another embodiment, the scan chain input flip-flops feature both existing input FFs for the component function and also additional input FFs. Likewise the scan chain output flip-flops feature both existing output FFs for the component function as well as additional output FFs. Because the local TMGs and TAAs are formed from existing flip-flops, this largely avoids additional design and component effort for BIST implementation. When the number of existing input flip-flops or output flip-flops corresponds to the number of scan inputs and outputs it is not even necessary to provide additional input FFs and output FFs.

### BRIEF DESCRIPTION OF THE DRAWINGS

Exemplary embodiments of the invention are shown in the drawings and described in more detail below. The drawings show:

FIG. 1 is a schematic representation of a part of an ASIC in accordance with the present invention, configured for performing block BIST.

FIG. 2 is a schematic representation of an ASIC in accordance with the invention, whereby the logical separation of the individual blocks during block BIST is illustrated.

FIG. 3 is a schematic part representation of the ASIC in accordance with the invention and similar to FIG. 1, that shows the principle of the connection BIST.

FIG. 4 is a schematic representation of an ASIC in accordance with the present invention, with the execution of the connection BIST shown including the ASIC pins.

FIG. 5 is a flowchart that represents the sequence of the procedure in accordance with the invention.

### DETAILED DESCRIPTION OF THE INVENTION

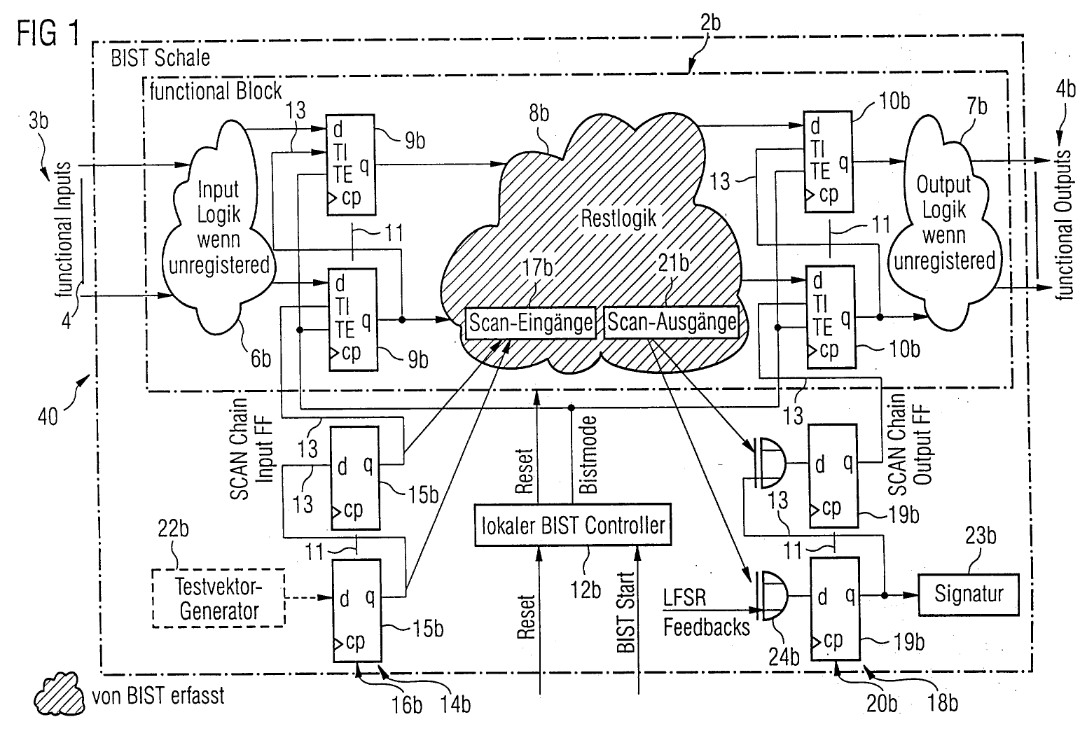

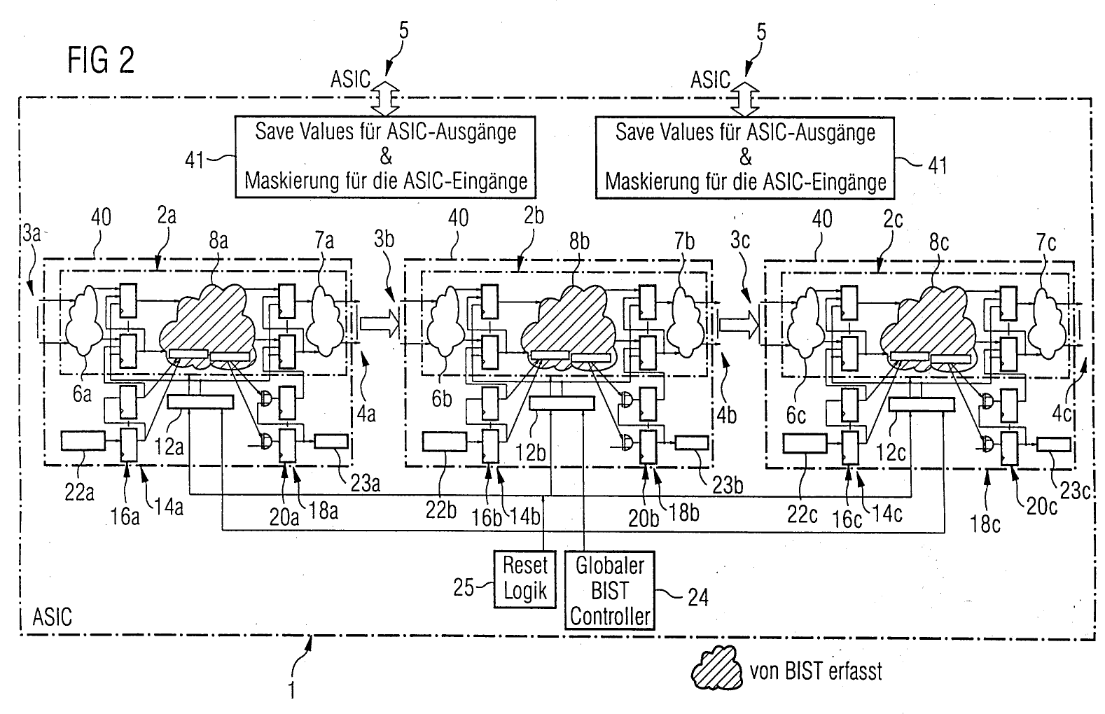

The following text describes an exemplary embodiment of the present invention with reference to an Application Specific Integrated Circuit (ASIC). As already stated in the introduction, each ASIC generally features an application-specific logic which can be subdivided, depending on the type and scope of the use of the ASIC, into a number of logic blocks. FIGS. 1 and 2 show this type of ASIC 1 with logic blocks 2a, 2b, 2c (referred to below as functional blocks). Functional blocks 2a, 2b, 2c are assigned a specific sub aspect of the ASIC application. Each functional block 2a, 2b, 2c receives data via functional inputs 3a, 3b, 3c which is processed block-specifically and is output via functional outputs 4a, 4b, 4c after processing.

The functional blocks, depending on the construction of a specific ASIC, are connected to a part (or to all) of the other functional blocks, as well as with a part or all of ASIC pins 5. To this extent the functional inputs 3a, 3b, 3c in normal operation of the ASIC receive data from selected other blocks 2a, 2b, 2c, as well as selected ASIC pins 5, and the process data of the functional blocks is forwarded via functional outputs 4a, 4b, 4c to selected other blocks 2a, 2b, 2c, as well as to selected ASIC pins 5.

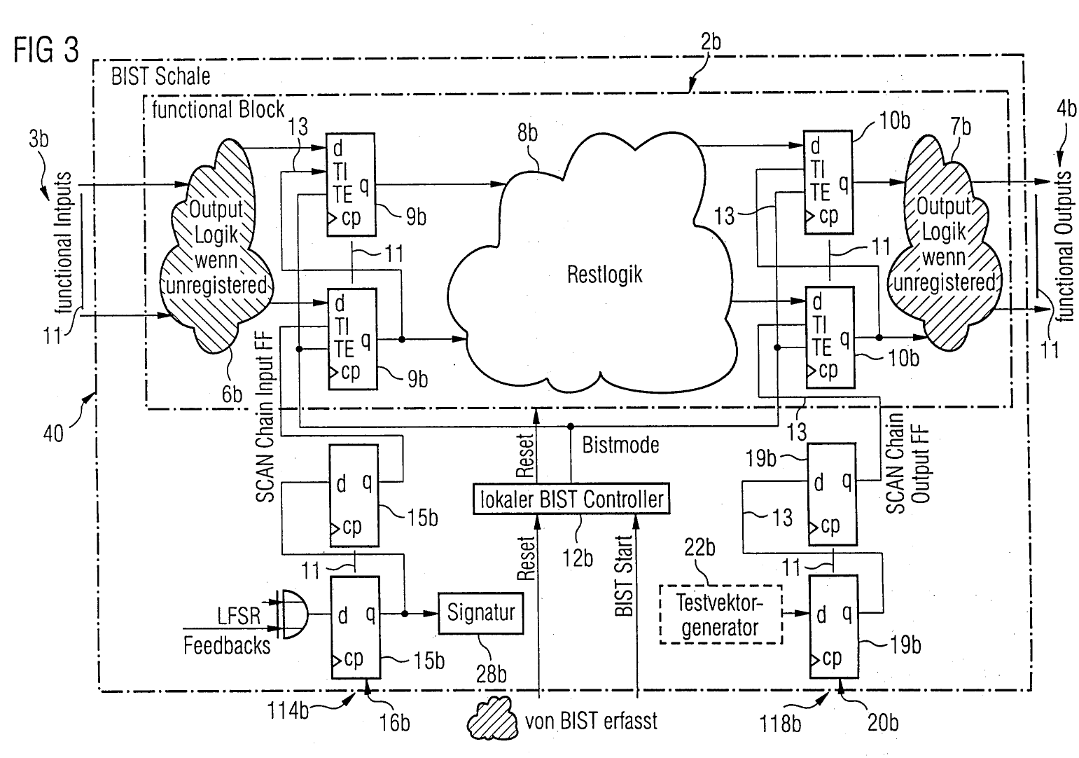

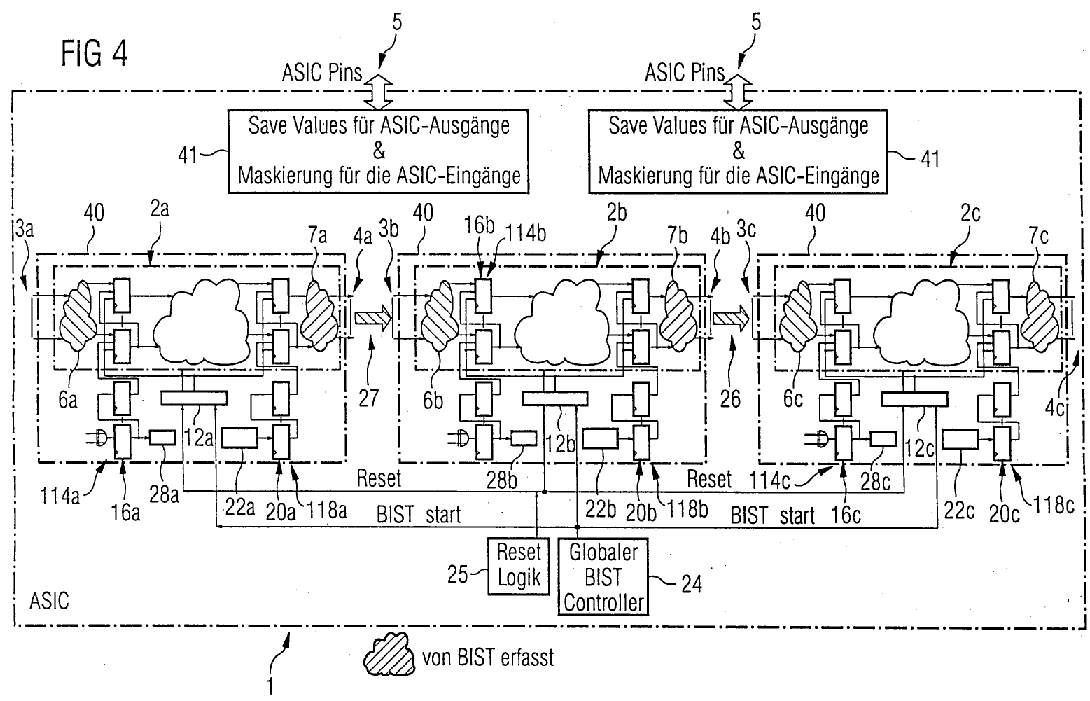

To achieve the greatest possible coverage for this type of ASIC 1 in test mode, i.e. when performing the Built-in-Self-Test (BIST), there is provision, in accordance with the invention, for a BIST procedure in two stages. The first stage is referred to as the block BIST and is shown in FIGS. 1 and 2. In the second stage of the procedure the connections between blocks 2a, 2b, 2c are tested in a stage that is referred to as a connection BIST, which is described below in further detail with regard to FIGS. 3 and 4.

In FIG. 1, a functional block 2b is shown embedded into a BIST shell 40 of ASIC 1. In BIST shell 40 the block-specific elements for performing the BIST are arranged. As well as functional inputs 3a and functional outputs 4b, functional block 2b features an output logic 7b and a residual logic 8b. Furthermore, input flip-flops or output flip-flops 9b are arranged between the input logic 6b and the residual logic 8b and output flip-flops or input flip-flops 10b are arranged between the residual logic 8b and the output logic 7b.

In normal operation, data reaches input logic 6b via the functional inputs 3b. Input-logic 6b comprises application-specific circuits such as Gates, multiplexers etc., but no registers or flip-flops. The input data then go from input logic 6b into the input FFs 9b, where they are clocked and entered into the residual logic 9b for processing. Residual logic 8b features the circuit elements necessary for block-specific processing on which there is no input logic 6b and output logic 7b. After processing by residual logic 8b the data arrives in the output flip-flop 10b and is passed on to output logic 7b. Output logic 7b, like input logic 6b, comprises application-specific switching elements such as gates, but no registers. From output logic 7b the data goes via functional outputs 4b from functional block 2b to other blocks 2a, 2c of ASIC 1 or to ASIC pins 5.

For production testing by the manufacturers of ASICs there are scan paths (not shown) provided in residual logic 8a, 8b. For the BIST these scan paths are divided up into shorter sub chains in order to reduce the BIST time. In order to provide test vectors for running through the sub scan chains, i.e. for performing the BIST, extra ASIC elements should be provided. For testing the residual logic 8b the input flip-flops 9b can be connected together into a shift register 14b by controlling a local BIST controller. In the preferred exemplary embodiment, shift register 14b is a Linear-Feedback-Shift-Register (LFSR). Where necessary, LFSR 14 not only includes the input FFs 9b that already exist for the normal function of ASIC 1, but also other additional input FFs 15b. Input Flip-Flops 9b and the additional input flip-flops 15b together form scan chain input flip-flops 16b and serve to stimulate scan inputs 17b on the input side in a residual logic 2b. Scan inputs 17b represent the inputs of the sub scan chains of residual logic 2b. The number of additional input FFs 15b is selected so that a sufficient number of scan chain input flip-flops 16b is available for scan inputs 17b.

Likewise on the output side, output flip-flops 10b can be combined for the BIST via shift lines 13 into a shift register 18b. In the preferred exemplary embodiment, shift register 18b is also a Linear-Feedback-Shift-Register (LFSR) 18b. In a similar way to that described with reference to LFSR 14b, additional output Flip-Flops 19b are provided, and together with output flip-flops 10b already available for the function, provide a sufficient number of scan chain output FFs 20b. Scan chain output flip-flops 20b serve as an output register for scan outputs 21b. Scan outputs 21b represent the outputs of the sub scan chains of residual logic 8b.

During the block BIST, the block boundaries are formed on the input side by scan chain input FFs 16b and on the output side by scan chain output FFs 20b. With the appropriate configuration these can serve directly as test pattern generator (TMG) or as test response evaluator (TAA) during the BIST.

As already mentioned, in the preferred exemplary embodiment, of the shift registers formed by registers 9b and 15b or registers 10b and 20b respectively form LFSRs 14b, 18b. In the case of this exemplary embodiment, no additional test vector generator is needed since the LFSR already implements this function.

In another preferred exemplary embodiment, scan chain input flip flops 16b and scan chain output flip-flops 10b nearly form a simple shift registers to shift in and shift out test data and for subsequent entry or acceptance of the test data. In this exemplary embodiment an explicit test vector generator 22b is provided for each functional block 2b. It would however also be conceivable for just one global test vector generator to be provided that supplies all functional blocks with test vectors.

Each block also features the logic for connecting together of the individual scan chains into a long chain or into several chains for manufacturer testing. Furthermore, each block BIST features at least one a signature register 23b. In the preferred exemplary embodiment, each block features a first and a second signature register.

To run the block BIST of an individual block 2b the following should be noted: The local BIST controller 12b receives from a global BIST controller 24 (see FIG. 2) a BIST start signal that is the BIST trigger, as well as a reset signal from a reset logic 25. The local BIST controller 12b forwards the reset signal to functional block 2b and sets all switching elements of the functional block to a pre-defined initial status. Furthermore, local BIST controller 12b outputs a BIST mode signal to scan chain input flip-flops 16b and scan chain output flip-flops 20b to connect these together to form LFSR 14b and LFSR 18b. The BIST mode signal determines during the BIST whether the shift registers “shift” or “accept” data. LFSR 14b then generates test data that is input to the relevant scan inputs 17b. After it has passed through the scan chains, the test data arrives via scan outputs at the relevant scan chain output flip-flops 20b. Scan chain output flip-flops 20b which form the LFSR serve here as test response evaluators (TAA) and can compress the data if necessary. TAA 18b finally outputs a signature to signature register 23b. The lower XOR symbol 24b in FIG. 1 serves both as a insertion point of the maximum periodic feedback of the LFSR 18b and also to record the data from a scan output 21b. XOR symbol 25b in its turn couples on one side a scan output 21b and shift register line 13 to one of the additional output flip flops 10b.

The method described above ensures that flip-flops of the corresponding block 2b are recorded for this block BIST. The area recorded by the block BIST is represented by the shaded area of the Reset logic.

It should be noted here that lines 11 in FIG. 1 stand for a large number of elements arranged above and below and lines 11. So although only two input flip-flops 9b are shown in FIG. 1, line 11 should however indicate that where necessary there are more than just two registers in the arrangement shown. This remark also applies to the other figures in this patent application.

With reference to FIG. 2, the interaction of the block-oriented block BIST is shown. For example, three functional blocks 2a, 2b, 2c are shown in FIG. 2. It should be noted here that for reasons of clarity only three blocks are shown in the figure. The principles of the present invention however are equally applicable to a component with any number of blocks. Blocks 2a, 2c each feature the same BIST-relevant elements, as were described with reference to FIG. 1, even if the block-specific input, output and residual logic 6a, 7a, 8a, 6c, 7c, 8c may well differ. The number of relevant scan chain input flip-flops 16a, 16b, 16c and scan chain output flip-flops 20a, 20b, 20c can also differ from block to block.

At ASIC level a reset signal is issued to local BIST controllers 12a, 12b, 12c for the block BIST by reset logic 25. In addition the global BIST controller 24 central sends a BIST start signal to local BIST controllers 12a, 12b, 12c. In response to the BIST start signal, the individual functional blocks are subjected to the block BIST under the control of the local BIST controller in order to test the residual logic 8a, 8b, 8c shown shaded in FIG. 2. After the block BIST described under FIG. 1 has executed the block-specific signature is present in each first signature register 23a, 23b, 23c which discloses any possible errors existing in the individual residual logic 8a, 8b, 8c.

With reference to FIGS. 3 and 4, the second stage of the BIST procedure in accordance with the invention, which is designated as a connection BIST, is now described. In this stage, at the ASIC level globally connections between blocks 2a, 2b, 2c and the parts not included by the block BIST, namely input logic 6a, 6b, 6c and output logic 7a, 7b, 7c are tested. It should be noted that within the framework of the connection BIST the input and output logic are conceptually assigned to the connections between the blocks. For these stages the roles of TMG 14a, 14b, 14c and of TAA 18a, 18b, 18c are swapped under the control of the Global BIST controller. In more precise terms TAA 18b of the first stage (Block BIST) serves in the second stage (connection BIST) as TMG 118b and test pattern generator 14b from the first stage serves as test response evaluator 114b in the second stage.

FIG. 3 shows a similar view of a part of ASIC 1, as in FIG. 1. However it shows the configuration of block 2b for the connection BIST. The same reference symbols of FIGS. 1 and 3 identify the same elements.

On the output side scan chain output cells 20b in their turn are connected together into a shift register 18b, in the preferred embodiment again an LFSR 18b. On instruction from global BIST Controller 24 (see FIGS. 2 and 4), they serve in this case as TMG 18b and input test data into output logic 7b, from where the test data is routed via functional outputs 4b and connecting lines 26 (see FIG. 4), if necessary, to functional inputs 3c of a downstream functional block 2c to subsequently arrive there in input logic 6c and scan chain input flip-flops 16c of block 2c.

On the input side test data from the TMG 18a of an upstream functional block 2a passes via connection lines 27 (see FIG. 4) to the functional inputs 3b of block 2b. This data passes through input logic 6b and thus arrives in the scan chain input flip-flops 16b. The scan chain input flip-flops 16b however, on instruction of global BIST controller 24 form TAA 14b in the connection BIST. After acceptance by TAA 114b and any compression necessary, the test data is entered into a second signature register 28b. The signature in the second register discloses errors which may possibly have been present in connections 26 and 27 or other elements, such as the input and output logic, as well as in the functional inputs and outputs. With gate 124b the insertion point of the maximum and periodic feedback of the LSFR is again indicated.

As already shown with reference to the block BIST in the preferred exemplary embodiment, LFSRs are used for shift registers 114b and 118b which makes a separate test vector generator superfluous. With another exemplary embodiment test pattern generator 22b is coupled to shift register 118b in order to form the TMG for the connection BIST. When a test vector generator is used for both BIST stages it should be noted that for the connection BIST a simple stimulation (fewer patterns because of the lower logic level) would suffice.

With reference to FIG. 4, the interaction of the connection BIST at ASIC level is now described. After conclusion of the first procedure, reset logic 25 outputs a new reset command to the local BIST controllers 12a, 12b, 12c in order to reset functional blocks 2a, 2b, 2c. Furthermore, global BIST controller 24 outputs a new BIST start signal to the local BIST controllers 12a, 12b, 12c in order to cause these to form the relevant shift registers again. Global BIST controller 24 ensures in this case however that the TAA and TMG operation is switched over dynamically. This enables connections between the functional blocks, inclusive of input and output logic 6a, 6b, 6c, 7a, 7b, 7c, to be tested in parallel to each other. At the end of the connection BIST the signatures, which where necessary disclose errors in the connections, are located in the second signature registers 28a, 28b, 28c.

Finally, in a global BIST Controller 24 signatures of the two BIST steps from the first and second signature registers 23a, 23b, 23c, 28a, 28b, 28c are collected and a resulting BIST overall signature is formed for ASIC 1. This BIST overall signature is output for external error analysis. Alternatively, the BIST overall signature could be compared with a pre-specified sequence in order merely to disclose the presence or absence of an error.

As shown by Box 41 in FIGS. 2 and 4, ASIC pins 5 are decoupled from the rest of the ASIC during the execution of the total BIST, i.e. masks are provided for the ASIC inputs and secure values for the ASIC outputs in order to avoid an error in the BIST but also possible damage through short circuits.

Although in the above exemplary embodiment the collection of the signatures of the two stages of the BIST is undertaken via two separate signature registers 23b, 28b, it is conceivable, in accordance with another exemplary embodiment, that each block only features a single register. In this case, individual signature registers are read out by the global BIST controller after the block BIST which stores the first signatures. The second signatures, that are obtained by the connection BIST, are initially also stored in the single signature registers and then read out by the global BIST controller, that creates an overall signature from the first and the second signatures or, as described above undertakes a comparison with a pre-specified signature.

Furthermore, it should be noted with regard to signature registers 23b, 28b that it is left to the expert as to how the signature should be transferred from the relevant shift registers. In FIGS. 1 and 3 serial transfer is indicated. However a parallel transfer and simultaneous compression is also possible.

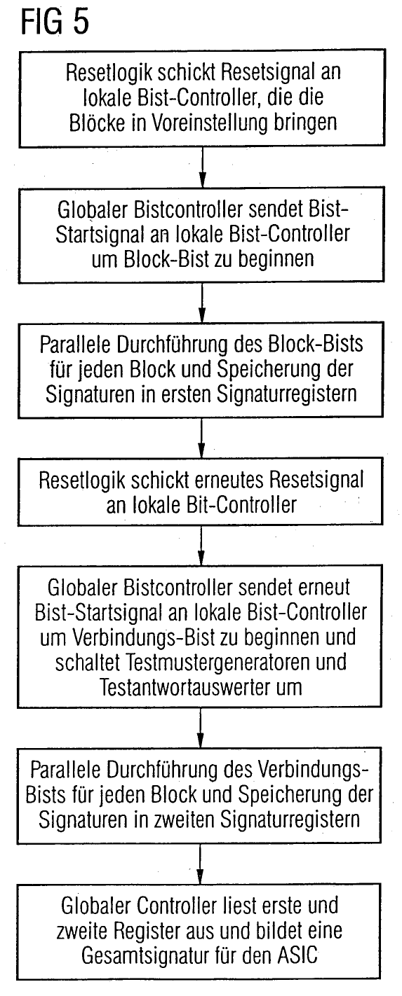

FIG. 5 shows a flowchart that gives an overview of the sequence of the BIST procedure of the preferred exemplary embodiment in accordance with the invention.

The provision of the BIST procedure in accordance with the invention described above and of an electronic component 1 that can execute this procedure produces the following benefits: For insertion of the test data into the residual logic 8a, 8b, 8c no additional logic is required, at least partially, the available input flip-flops 9a, 9b, 9c being used for this purpose. The test data evaluation by TAA 114b, 18b is also undertaken partially by the existing output flip-flops 10a, 10b, 10c present in the circuit. Furthermore, the TAA can also function as TMG 118 and vice versa, which reduces the number of additional elements required for executing the BIST. Finally the block BIST procedure that is executed in parallel his extended by the completeness of the total BIST procedure as regards coverage of the connections.

In general, the invention described previously can be used in integrated circuits, but in particular in ASICs. Above all with complex ASICs (high number of gates, a number of clock domains) this type of “Design-for-Tests” offers the advantage during the design stage of clarity and thereby of reduction in error probability, without adversely affecting test coverage. Furthermore suppliers of computer-aided engineering-tools could use the idea for automatically modifying a design in such a way that the problems addressed would be solved.

What is claimed is:

1. A method for testing an electronic component with integrated circuits combined into functional blocks, with the functional blocks having connections therebetween and a relevant residual logic, comprising:
testing the residual logic-of the functional blocks by entering test data into the residual logic and output of a first signature for each block; and
testing the connections between the blocks by transferring test data via the connections and output of a second signature.

2. The method in accordance with claim 1, wherein the first and second signatures are collected at a global test controller and an overall signature is created for component.

3. The method in accordance with claim 1, wherein the testing of the residual logic of the relevant blocks is undertaken in parallel.

4. The method in accordance with claim 1, wherein the testing of the connections is undertaken in parallel.

5. The method in accordance with claim 1, wherein the testing of the connections includes the testing of input and output logic.

6. The method in accordance with claim 1, wherein each functional block features scan chain input flip-flops and scan chain output flip-flops, whereby for testing of the residual logic and testing the connections the scan chain input flip-flops and scan chain output flip-flops are connected together by a local controller into a shift register in each case.

7. Method in accordance with claim 6, wherein the scan chain input flip-flops and scan chain output flip-flops are each connected together into a Linear-Feedback-Shift-Register.

8. The method in accordance with claim 6, wherein the scan chain input flip-flops and/or scan chain output flip-flops and are coupled with a test vector generator to provide test data for the shift registers.

9. The method in accordance with claim 1, wherein, for parallel testing of the residual logic, the scan chain input flip-flops serve as test pattern generators and the scan chain output flip-flops as a test result evaluators and for testing the connections the scan chain input flip-flops serve as test response evaluators and the scan chain output flip-flops serve as test pattern generators.

10. An electronic component, comprising:
integrated circuits combined into functional blocks, whereby the functional blocks have connections therebetween and a residual logic in each case, each functional block having a first and a second shift register, where the first shift register provides test data for testing the residual logic and, after the test data has passed through the residual logic and is accepted by the second shift register, is provided as the first signature, and
wherein for testing the connections, the second shift register provides the test data for testing the connections which is accepted by the first shift register after the test data has passed through the output and input logic and is provided as a second signature

11. The electronic component in accordance with claim 10, further comprising a global test controller which receives the first and second signatures from functional blocks and creates an overall signature for the component with the first and second signatures.

12. The electronic component in accordance with claim 10, wherein each functional block has a local test controller that controls the first and second shift register.

13. The electronic component in accordance with claim 11, wherein the global test controller is connected to the local test controllers of the functional blocks and sends a start signal to the controllers, such that the local test controllers, depending on the start signal, switch the first and second shift registers dynamically into a shift and accept mode and execute the test of the electronic component.

14. The electronic component according to claim 13, further comprising a reset logic that is connected to local test controllers of the functional blocks and sends a reset signal to the controllers, wherein the local test controllers responding to the reset signal, reset the corresponding functional blocks.

15. The electronic component in accordance with claim 14, the testing of the residual logic of the individual blocks is undertaken in parallel.

16. The electronic component in accordance with claim 14, wherein the testing of the connections is undertaken in parallel.

17. The electronic component in accordance with claim 10, wherein the testing of the connections includes the testing of the input and output logic of the functional blocks.

18. The electronic component in accordance with claim 10, wherein the first shift register has scan chain input flip-flops to stimulate scan inputs and the second shift register has scan chain output flip-flops that are coupled to scan outputs.

19. The electronic component in accordance with claim 18, wherein the scan chain input flip-flops has input flip-flops that exist for the component function as well as additional input flip-flops.

20. The electronic component in accordance with claim 18, wherein the scan chain output flip-flops have output flip-flops that exist for the component function as well as additional output flip-flops.

21. The electronic component in accordance with claim 18, wherein the first and/or second shift register is coupled to a test vector generator.

22. The electronic component in accordance with claim 18, wherein the first and the second shift register is a Linear Feedback Shift Register.
